(19) United States
(12) Patent Application Publication
(10) Pub. No.: US 2022/0166157 A1
(43) Pub. Date: May 26, 2022

(54) HIGH DENSITY CONNECTOR ASSEMBLY

(71) Applicant: 3M INNOVATIVE PROPERTIES COMPANY, St. Paul, MN (US)

(72) Inventors: YunLong Qiao, Singapore (SG); Saujit Bandhu, Singapore (SG); Kok Hoe Lee, Singapore (SG); Vincent Tan, Singapore (SG)

(21) Appl. No.: 17/593,569

(22) PCT Filed: Mar. 23, 2020
(86) PCT No.: PCT/IB2020/052715

§ 371 Date: Sep. 21, 2021

Related U.S. Application Data
(60) Provisional application No. 62/833,090, filed on Apr. 12, 2019.

(51) Int. Cl. H01R 12/62; H05K 1/11

(52) U.S. Cl. CPC H01R 12/62; H05K 1/117; H05K 2201/09409; H05K 2201/094; H05K 2201/10356; H05K 2201/10189

(57) ABSTRACT

A connector assembly comprising a housing, first and second circuit boards, and substantially flat cables. The housing includes a mating end for mating with a mating connector and an opposite cable end for receiving a cable. The first and second circuit boards are disposed inside the housing. Each circuit board includes a plurality of conductive front pads disposed closer to the mating end of the housing and a plurality of conductive rear pads disposed closer to the cable end of the housing and electrically connected to the front pads. At least one front pad of the first circuit board faces, aligns with, and is electrically connected to, at least one rear pad of the second circuit board. The substantially flat cables include a plurality of conductors. The uninsulated front ends of the conductors of the cables terminate at the corresponding rear pads of the first circuit board.

### TECHNICAL FIELD

The present disclosure generally relates to connector assemblies, particularly high density connector assemblies.

### BACKGROUND

Quad small form-factor pluggable (QSFP) is a widely used interface for data center external IO connection applications. As the industry is moving toward a higher data rate per cable, the quad small form-factor pluggable double density (QSFP-DD) interface has been introduced to carry double the data capacity of a QSFP cable assembly.

### SUMMARY

In some cases, it may be desired to increase the data carrying capacity of a connector assembly by fitting more cables into a limited space available in the cable assembly. Since the overall size of the cable assembly interface is often standardized, it may be desired to position a higher density of cables within an available cross section space without changing the dimensions of a metal shell within which a QSFP or QSFP-DD interface is provided.

Various aspects and embodiments described herein relate to a connector assemblies and connectors.

Some aspects of the disclosure relate to a connector assembly including a housing having top and bottom housing portions assembled to each other and defining a housing cavity therebetween. The housing includes a mating end for mating with a mating connector and an opposite cable end for receiving one or more cables. The connector assembly includes first and second circuit boards disposed in the housing cavity. Each circuit board includes an upper surface and an opposing lower surface, and a front edge and a rear edge opposite the front edge.

The first circuit board is disposed closer to the cable end and farther from the mating end. The first circuit board includes a plurality of conductive front pads disposed on the lower surface proximate the front edge. The first circuit board further includes a plurality of conductive rear pads disposed on the upper and lower surfaces proximate the rear edge and electrically connected to the front pads. The rear pads form first and second rows of rear pads disposed on the upper surface, and third and fourth rows of rear pads disposed on the lower surface. The second circuit board is disposed closer to the mating end and farther from the cable end. The second circuit board includes a plurality of conductive front pads disposed on the upper and lower surfaces proximate the front edge. The second circuit board further includes a plurality of conductive rear pads disposed on the upper surface proximate the rear edge and electrically connected to the front pads. The front pads on the lower surface of the first circuit board faces, aligns with, and is electrically connected to, the rear pads on the upper surface of the second circuit board. The connector assembly further includes substantially flat first through fourth cables including a plurality of conductors. Uninsulated front ends of the conductors of the first through fourth cables terminate at the corresponding rear pads of the respective first through fourth rows of the rear pads of the first circuit board.

Other aspects of the disclosure relate to a connector including a housing having a mating end for mating with a mating connector and an opposite cable end for receiving a cable. The connector further includes first and second circuit boards disposed inside the housing. Each circuit board includes a plurality of conductive front pads disposed closer to the mating end of the housing and a plurality of conductive rear pads disposed closer to the cable end of the housing and electrically connected to the front pads. At least one front pad of the first circuit board faces, aligns with, and is electrically connected to, at least one rear pad of the second circuit board.

Some other aspects of the disclosure relate to a connector including a housing and a plurality of circuit boards disposed inside the housing. The housing defines an elongated opening therein having a smaller height and a larger width. At least one of the circuit boards extends through the opening. A combined thickness of the plurality of circuit boards is greater than the height of the opening.

These and other aspects of the present application will be apparent from the detailed description below. In no event, however, should the above summaries be construed as limitations on the claimed subject matter, which subject matter is defined solely by the attached claims.

### BRIEF DESCRIPTION OF DRAWINGS

The various aspects of the disclosure will be discussed in greater detail with reference to the accompanying figures where,

FIGS. 1 and 2 schematically show different views of a connector assembly according to an aspect of the disclosure;

FIG. 3 schematically shows a connector according to an aspect of the disclosure;

FIG. 4 schematically shows a mating connector for mating with a connector assembly according to an aspect of the disclosure;

FIG. 5 schematically shows an exploded view of a connector assembly according to some aspects of the disclosure;

FIGS. 6-9 schematically show different views of the circuit boards of a connector assembly according to some aspects of the disclosure;

FIGS. 10-11 schematically show different views of the circuit boards aligned with each other according to certain aspects of the disclosure;

FIG. 12 schematically shows a cross section of the connector assembly according to certain aspects of the disclosure;

FIGS. 13-14 schematically show cables assembled to the circuit boards according to an aspect of the disclosure;

FIG. 15 schematically shows a detailed view of the cables assembled to the circuit board according to an aspect of the disclosure;

FIGS. 16-17 schematically show different cross sectional views of the connector assembly according to certain aspects of the disclosure;

FIG. 18 schematically shows a side view of the connector assembly with a pull tab assembled to housing portions of the connector assembly; and

FIG. 19 schematically shows a cross sectional view of the connector according to another aspect of the disclosure.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION OF ILLUSTRATIVE EMBODIMENTS

In the following detailed description, reference is made to the accompanying drawings that form a part hereof, and in which are shown by way of illustration several specific embodiments. It is to be understood that other embodiments are contemplated and may be made without departing from the scope or spirit of the present disclosure.

The connector assembly according to this disclosure may be a quad small form-factor pluggable (QSFP) connector assembly. In other embodiments, the connector assembly may be a quad small form-factor pluggable double density (QSFP-DD) connector assembly.

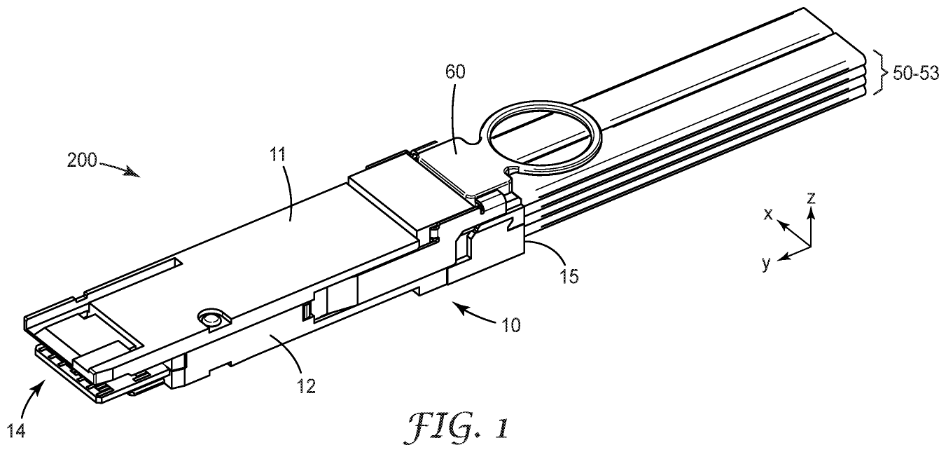

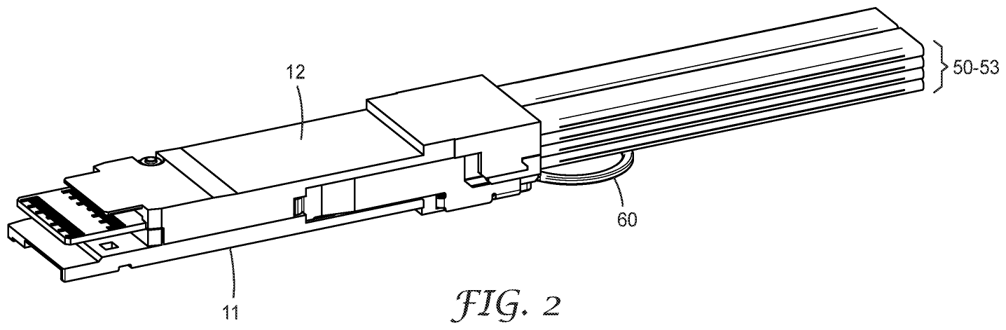

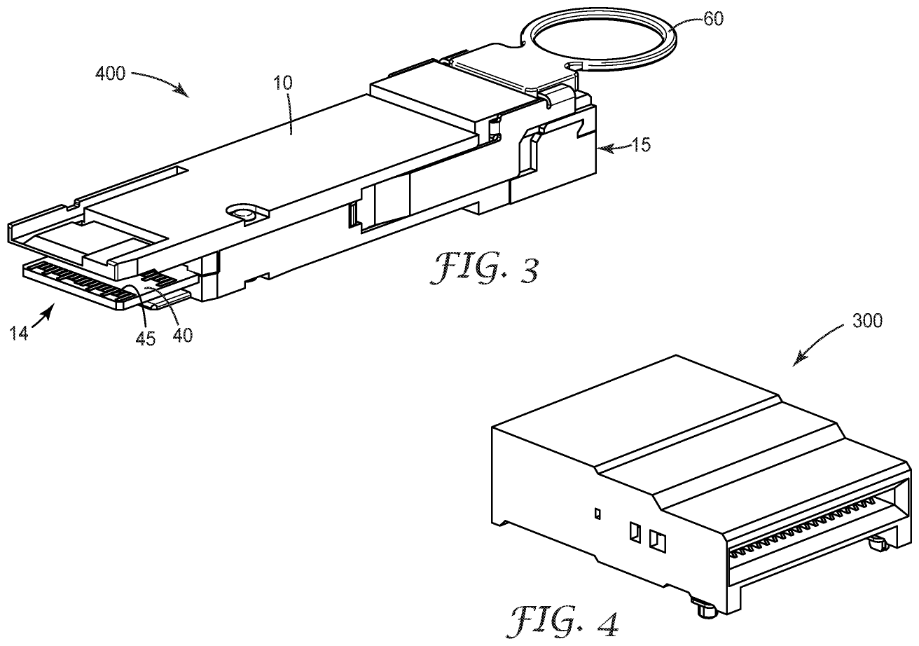

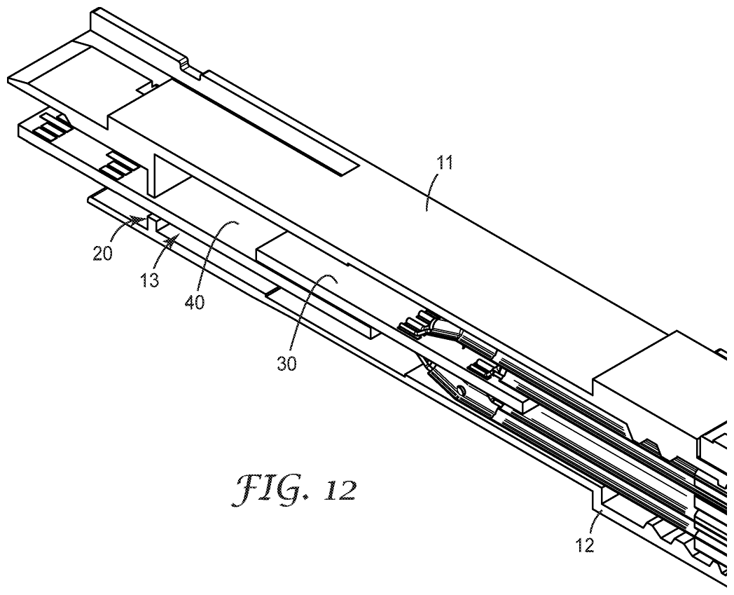

A connector assembly according to some embodiments as illustrated in FIGS. 1-9 include a housing (10) having a top (11) and bottom (12) housing portions assembled to each other. As shown in FIG. 12, the top and bottom housing portions (11, 12) combine to define a housing cavity (13) therebetween. The top and bottom housing portions (11, 12) may be made of metal, for example.

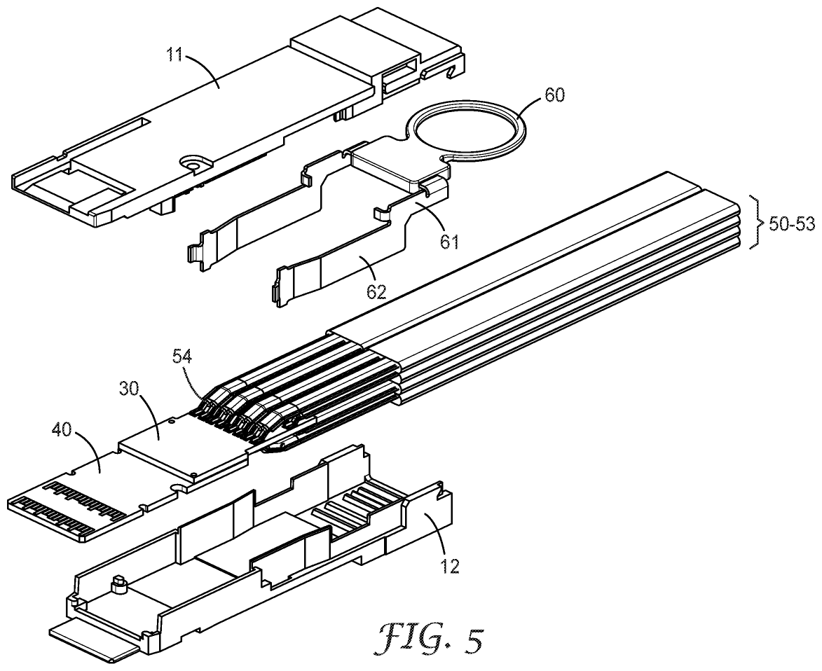

The housing (10) has a mating end (14) for mating with a mating connector (300) and an opposite cable end (15) for receiving one or more cables (50-53). As shown best in FIGS. 5 and 12, first (30) and second (40) circuit boards are disposed in the housing cavity (13) to electrically couple to one or more conductors of cables (50-53), as will be described further below. The mating connector (300) is typically connected to a PCB, for instance, the second circuit board (40). In some aspects, the connector assembly (200) may include a pull tab (60) for disengaging the connector assembly from a mating connector. A pulling of an operating portion of the pull tab (60) unlatches the mating connector from the connector assembly (200). The pull tab (60) may include a first portion (61) attached to the top housing portion (11), and a different second portion (62) attached to the bottom housing portion (12), as best shown in FIG. 18.

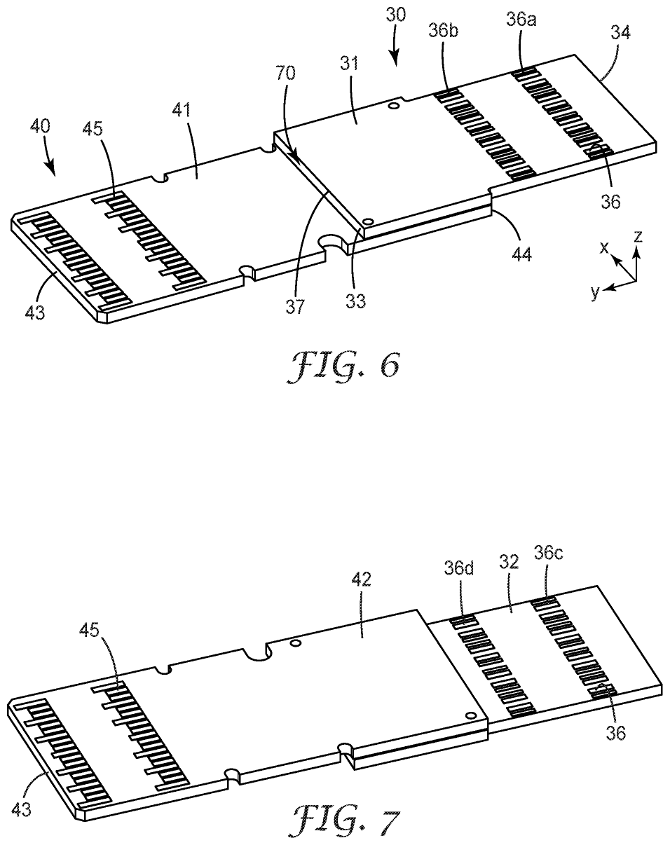

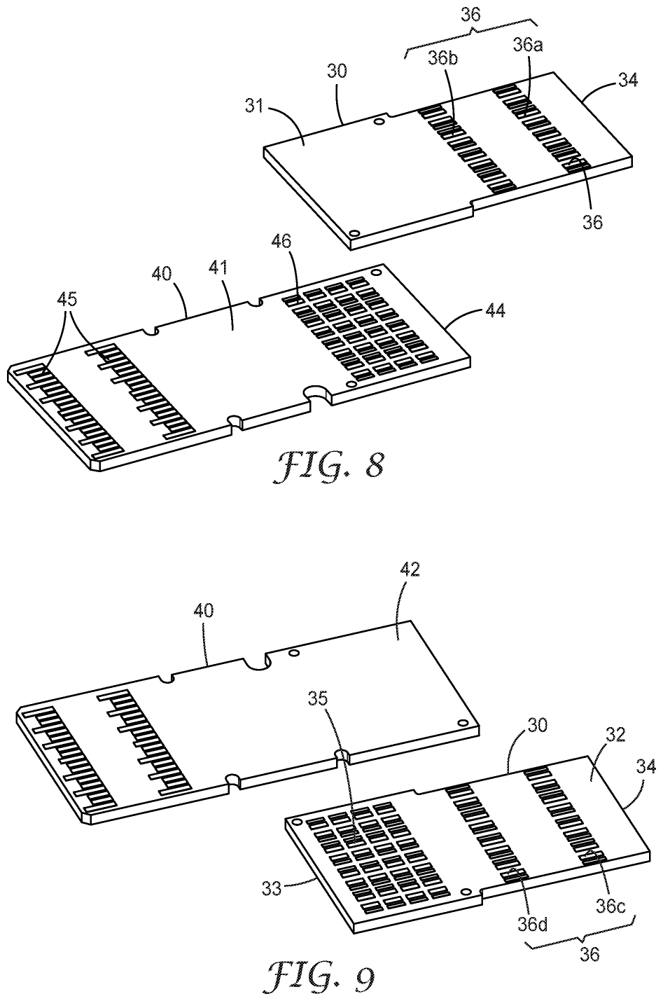

Each circuit board (30,40) has an upper surface (31, 41) and an opposing lower surface (32, 42) and a front edge (33, 43) and a rear edge (34, 44) opposite the front edge as best shown in FIGS. 6 and 7. The first circuit board (30) is disposed closer to the cable end (15) and farther from the mating end (14). According to certain aspects as best shown in FIG. 9, the first circuit board (30) includes a plurality of conductive front pads (35) disposed on the lower surface (32) proximate the front edge (33). As shown in FIGS. 8 and 9, the first circuit board (30) includes a plurality of conductive rear pads (36) disposed on the upper (31) and lower surfaces (32) proximate the rear edge (34). The plurality of conductive rear pads (36) are electrically connected to the front pads (35) e.g., via one or more conductive pathways or traces defined in the first circuit board (30). The rear pads (36) of the first circuit board (30) include a plurality of rows of rear pads disposed on the upper and lower surfaces of the first circuit board. In some embodiments as best seen in FIGS. 8 & 9, the rear pads (36) form a first (36a) and second (36b) rows of rear pads disposed on the upper surface (31), and third (36c) and fourth (36d) rows of rear pads disposed on the lower surface (32) of the first circuit board (30).

The second circuit board (40) is disposed closer to the mating end (14) and farther from the cable end (15). The second circuit board (40) includes a plurality of conductive front pads (45) disposed on the upper and lower surfaces (41, 42) proximate the front edge (43). The front pads (45) are configured to engage terminals of a mating connector (300). The second circuit board further includes a plurality of conductive rear pads (46) disposed on the upper surface (41) proximate the rear edge (44). The plurality of conductive rear pads (46) are electrically connected to the front pads (45) e.g., via one or more conductive pathways or traces defined in the second circuit board (40). In some aspects of the disclosure, the front pads (35) on the lower surface (32) of the first circuit board (30) faces, aligns with, and is electrically connected to, the rear pads (46) on the upper surface (41) of the second circuit board (40).

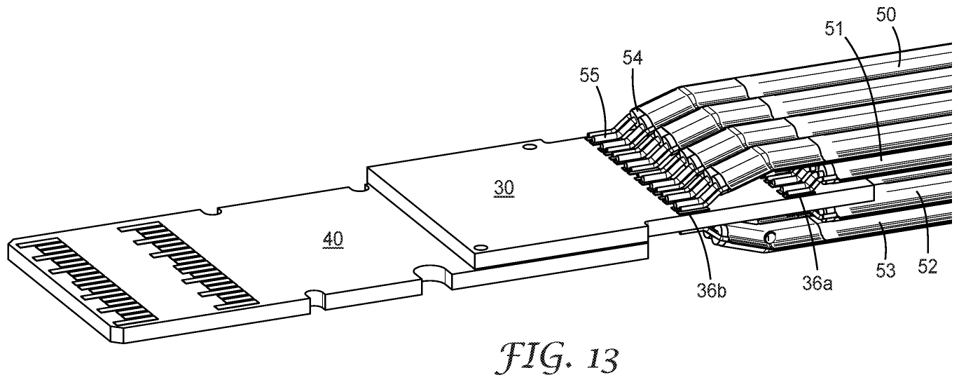

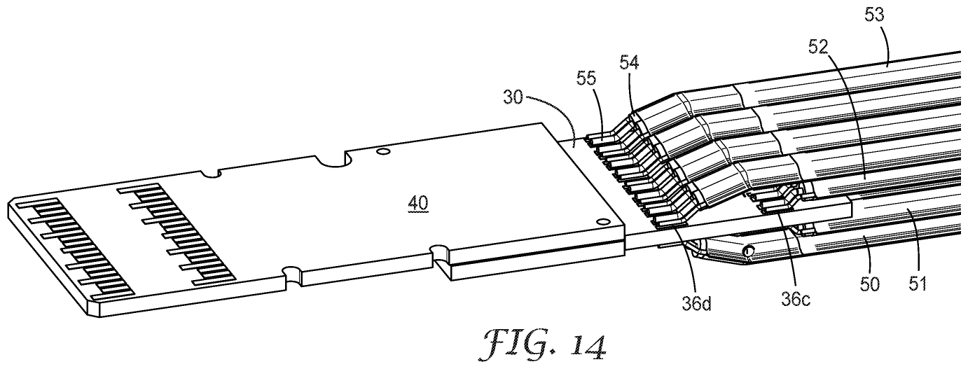

The connector assembly (200) includes substantially flat first through fourth cables (50, 51, 52, 53). Each cable (50, 51, 52, 53) includes a plurality of conductors (54) terminated at the corresponding rear pads (36) of the first circuit board (30). As best shown in FIGS. 13 and 14, uninsulated front ends (55) of the conductors (54) of the first through fourth cables (50, 51, 52, 53) terminate at the corresponding rear pads (36) of the respective first through fourth rows (36a, 36b, 36c, 36d) of the rear pads of the first circuit board (30).

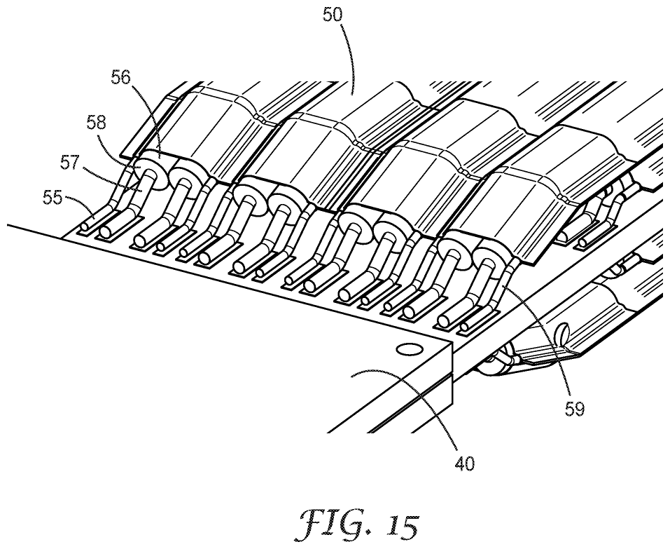

In some aspects, as best seen in FIG. 15, the first through fourth cables (50, 51, 52, 53) include a plurality of insulated conductors (56). Each insulated conductor includes a conductor (57) surrounded by an insulating material (58). In some embodiments, the first through fourth cables (50, 51, 52, 53) may include a plurality of uninsulated drain conductors (59).

In some cases, the conductor (57) may have a diameter not greater than 24 American Wire Gauge (AWG). In some other cases, the conductor may have a diameter not greater than 22 AWG, and in some other cases, the conductor may have a diameter not greater than 20 AWG.

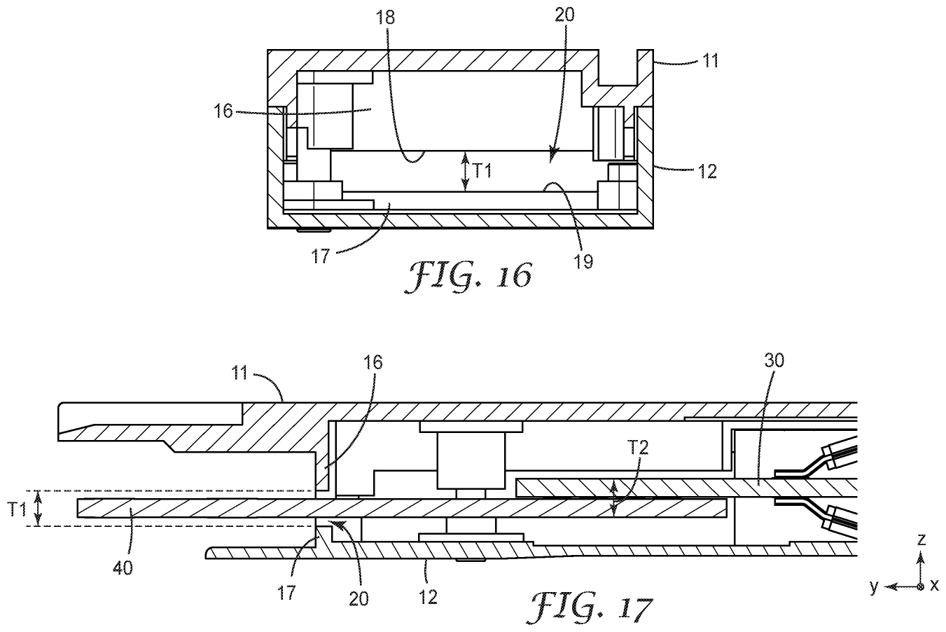

In some aspects of the disclosure as illustrated in FIGS. 16 and 17, the top housing portion (11) includes a top interior wall (16) and the bottom housing portion (12) includes a bottom interior wall (17). The top and bottom interior walls (16, 17) are disposed in the housing cavity away from the cable end (15) and mating end (14) and are oriented orthogonal to the second circuit board (40) and a mating direction (y) of the connector assembly.

In some embodiments, free ends (18, 19) of the top and bottom interior walls (16, 17) are spaced apart by a distance T1 along a direction orthogonal to the second circuit board (40). The first and second circuit boards (30, 40) may have a combined thickness T2, where T2>T1. In some other aspects, the free ends (18, 19) of the top and bottom interior walls (16, 17) generally face, and are aligned with, each other. The free ends (18, 19) define an opening (20) therebetween, the opening having a height equal to T1.

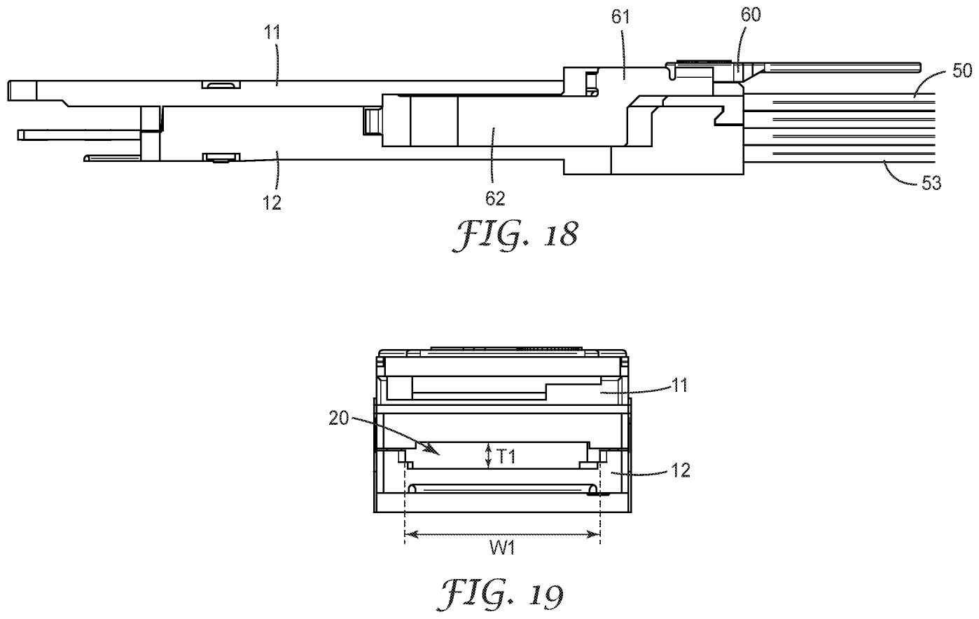

Some aspects of the disclosure relate to a connector (400) including a housing (10) and a plurality of circuit boards (30, 40) disposed inside the housing (10). In some embodiments, the housing may be made of metal. The housing (10) defines an elongated opening (20) having a smaller height (T1) and a larger width (W1) as can be best seen in FIG. 19. In some embodiments as shown in FIG. 17, at least one of the plurality of circuit boards (40) extends through the opening (20). A combined thickness (T2) of the plurality of circuit boards is greater than the height (T1) of the opening.

In some aspects, the plurality of circuit boards are stacked along a thickness direction (z) of the circuit boards. The circuit boards in at least one pair of adjacent circuit boards (30, 40), are offset relative to each other along a mating direction (y) of the connector. In an aspect as shown in FIG. 6, the first and second circuit boards (30, 40) define a step (70) therebetween at a front edge (37) of the first circuit board proximate the front pads (35) of the first circuit board (30). The step (70) may be formed due to the stacked up arrangement of the first and second circuit boards (30, 40).

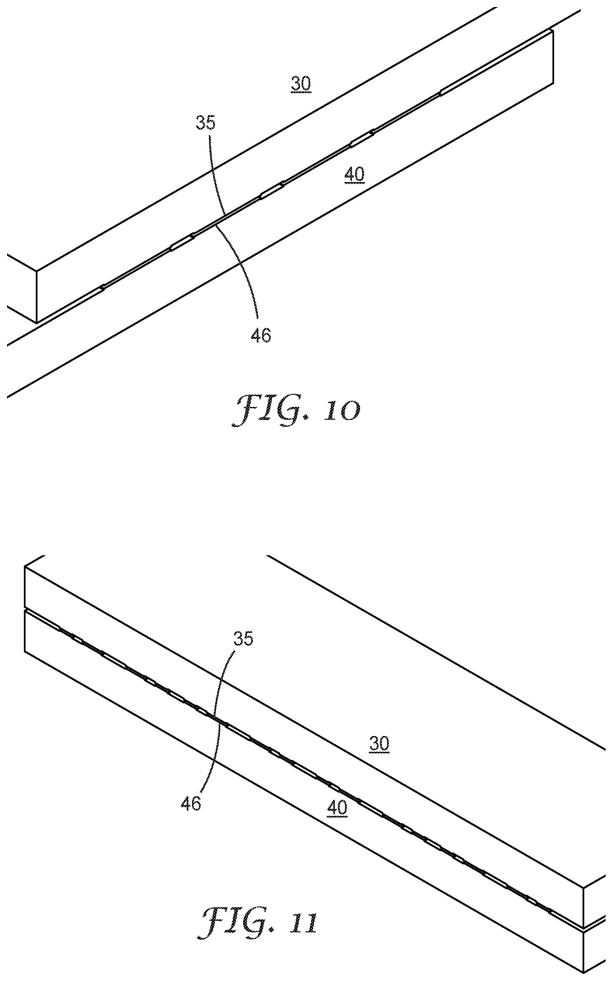

In some aspects, the plurality of circuit boards includes first (30) and second (40) circuit boards each having a plurality of electrically conductive pads (35, 36, 45, 46). As can be seen in FIGS. 10 and 11, at least one pad (35) of the first circuit board (30) faces, aligns with, and is electrically connected to at least one pad (46) of the second circuit board (40).

The housing (10) of the connector (400) has a mating end (14) for mating with a mating connector (300) and an opposite cable end (15) for receiving a cable (50). Each circuit board (30, 40) has a plurality of conductive front pads (35, 45) disposed closer to the mating end (14) of the housing (10) and a plurality of conductive rear pads (36, 46) disposed closer to the cable end (15) of the housing (10). The conductive rear pads (36, 46) are electrically connected to the front pads (35, 45) e.g., via one or more conductive pathways or traces defined in the circuit boards (30, 40). In some aspects, at least one front pad of the first circuit board (30) faces, aligns with, and electrically connected to, at least one rear pad of the second circuit board (40). In some other aspects, the front pads of the first circuit board (30) face, are aligned with, and are electrically connected to, the rear pads of the second circuit board (40).

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific Embodiments shown and described without departing from the scope of the present disclosure. This application is intended to cover any adaptations or variations of the specific Embodiments discussed herein. Therefore, it is intended that this disclosure be limited only by the claims and the equivalents thereof.

1. A connector assembly, comprising:
a housing comprising top and bottom housing portions assembled to each other and defining a housing cavity therebetween, the housing comprising a mating end for mating with a mating connector and an opposite cable end for receiving one or more cables;
first and second circuit boards disposed in the housing cavity, each circuit board comprising:
an upper surface and an opposing lower surface; and
a front edge and a rear edge opposite the front edge;
the first circuit board disposed closer to the cable end and farther from the mating end and comprising:
a plurality of conductive front pads disposed on the lower surface proximate the front edge; and
a plurality of conductive rear pads disposed on the upper and lower surfaces proximate the rear edge and electrically connected to the front pads, the rear pads forming first and second rows of rear pads disposed on the upper surface, and third and fourth rows of rear pads disposed on the lower surface;
the second circuit board disposed closer to the mating end and farther from the cable end and comprising:
a plurality of conductive front pads disposed on the upper and lower surfaces proximate the front edge; and
a plurality of conductive rear pads disposed on the upper surface proximate the rear edge and electrically connected to the front pads;
the front pads on the lower surface of the first circuit board facing, aligned with, and electrically connected to, the rear pads on the upper surface of the second circuit board; and
substantially flat first through fourth cables comprising a plurality of conductors, uninsulated front ends of the conductors of the first through fourth cables terminated at the corresponding rear pads of the respective first through fourth rows of the rear pads of the first circuit board.

2. The connector assembly of claim 1, wherein the first through fourth cables comprise a plurality of insulated conductors, each insulated conductor comprising a conductor surrounded by an insulating material, the conductor having a diameter not greater than 20 American Wire Gauge (AWG).

3. The connector assembly of claim 1, wherein the top and bottom housing portions comprise respective top and bottom interior walls disposed in the housing cavity away from the cable and mating ends and oriented orthogonal to the second circuit board and a mating direction of the connector assembly, free ends of the top and bottom interior walls spaced apart by a distance T1 along a direction orthogonal to the second circuit board, the first and second circuit boards having a combined thickness T2, T2>T1.

4. The connector assembly of claim 1 being a quad small form-factor pluggable (QSFP) connector assembly, or a quad small form-factor pluggable double density (QSFP-DD) connector assembly.

5. A connector, comprising:
a housing comprising a mating end for mating with a mating connector and an opposite cable end for receiving a cable; and
first and second circuit boards disposed inside the housing, each circuit board comprising a plurality of conductive front pads disposed closer to the mating end of the housing and a plurality of conductive rear pads disposed closer to the cable end of the housing and electrically connected to the front pads, at least one front pad of the first circuit board facing, aligned with, and electrically connected to, at least one rear pad of the second circuit board.

6. The connector of claim 5, wherein the first and second circuit boards define a step therebetween at a front edge of the first circuit board proximate the front pads of the first circuit board.

7. The connector of claim 5, wherein the front pads of the first circuit board face, are aligned with, and are electrically connected to, the rear pads of the second circuit board.

8. A connector comprising a housing and a plurality of circuit boards disposed inside the housing, the housing defining an elongated opening therein having a smaller height and a larger width, at least one of the circuit boards extending through the opening, a combined thickness of the plurality of circuit boards being greater than the height of the opening.

9. The connector of claim 8, wherein the plurality of circuit boards comprises first and second circuit boards each having a plurality of electrically conductive pads, at least one pad of the first circuit board facing, aligned with, and electrically connected to at least one pad of the second circuit board.

10. The connector of claim 8, wherein the plurality of circuit boards are stacked along a thickness direction of the circuit boards, and the circuit boards in at least one pair of adjacent circuit boards, are offset relative to each other along a mating direction of the connector.

11. The connector assembly of claim 1, wherein the first through fourth cables comprise a plurality of uninsulated drain conductors

12. The connector assembly of claim 3, wherein the free ends of the top and bottom interior walls generally face, and are aligned with, each other and define an opening therebetween, the opening having a height equal to T1.

13. The connector assembly of claim 1 further comprising a pull tab for disengaging the connector assembly from a mating connector, a first portion of the pull tab attached to the top housing portion, and a different second portion of the pull tab attached to the bottom housing portion.

14. The connector assembly of claim 1, wherein the top and bottom housing portions are made of metal.

15. The connector of claim 5, wherein the housing is made of metal.
